(19) United States
(12) Patent Application Publication
(10) Pub. No.: US 2026/0059686 A1
(43) Pub. Date: Feb. 26, 2026

(54) WIDEBAND / MULTIBAND ADD-ON METASURFACE MODULES FOR ENHANCED NOISE SUPPRESSION IN SERVER INFRASTRUCTURE

(71) Applicant: Dell Products L.P., Round Rock, TX (US)

(72) Inventors: Tejinder Singh, Manotick (CA); Navjot Kaur Khaira, Manotick (CA)

(21) Appl. No.: 18/810,941

(22) Filed: Aug. 21, 2024

(51) Int. Cl. H05K 7/14; H05K 7/20

(52) U.S. Cl. CPC H05K 7/1488; H05K 7/20736

(57) ABSTRACT

The technology described herein is directed towards modular metasurfaces arranged with unit cells for narrowband, wideband and/or multiband sound absorption, in which the unit cells are based on Helmholtz resonators that are deployed in a server rack, proximate to a server, without substantially obstructing airflow from the server fan(s). Each sound absorbing unit-cells is designed and constructed based on a specific resonance frequency, and includes a neck portion and air chamber dimensioned to resonate at the desired resonance frequency and thereby inverse phase cancel corresponding narrowband frequencies of incoming sound waves. Differently-dimensioned unit cells can be built into a single metasurface module, thereby facilitating wideband and/or multiband sound absorption with that metasurface. The modular metasurfaces can be attached to the sidewalls of a server rack, or positioned in otherwise empty slots above and below a server, optionally coupled to blanking panels for covering the openings of those slots.

### BACKGROUND

Acoustic absorbers are specialized materials or structures designed to mitigate the effects of sound reflections, echoes, and reverberations in various environments. These absorbers function by capturing sound waves and converting their energy into heat, effectively reducing the intensity of the sound waves and preventing them from bouncing off surfaces and causing unwanted sound reflections. They are typically engineered using porous materials with intricate structures that allow sound waves to penetrate deep into the material, where the acoustic energy is dissipated as thermal energy through friction and air resistance.

Existing acoustic absorbers come in various forms, including foam panels, fabric-wrapped panels, diffusers, bass traps, and more. One of the problems with existing acoustic absorbers is that they are not desirable in certain heat-sensitive environments. For example, servers generate a lot of heat and thus are designed with fans to cool dissipate the heat; however, fans can generate a lot of annoying noise. Using existing acoustic absorbers to absorb server noise reduces the noise, but can significantly reduce dissipation of the heat generated by servers, which can result in high heat levels that can reduce server performance and possibly cause a server to shut down to avoid damage from overheating.

### BRIEF DESCRIPTION OF THE DRAWINGS

The technology described herein is illustrated by way of example and not limited in the accompanying figures in which like reference numerals indicate similar elements and in which:

FIG. 1 is a top-view representation of example metasurfaces with Helmholtz resonator unit cells deployed as metasurface modules on the side walls of a server rack for noise cancellation emanating from a server, in accordance with various example embodiments and implementations of the subject disclosure.

FIG. 2 is a three-dimensional (3D) perspective view representation of example metasurfaces with Helmholtz resonator unit cells deployed on the side walls of a server rack for noise cancellation emanating from a server, in accordance with various example embodiments and implementations of the subject disclosure.

FIG. 3 is a representation of example metasurface modules designed and 3D-printed for noise cancellation, based on a detected peak frequency, in accordance with various example embodiments and implementations of the subject disclosure.

FIG. 4 is a is a three-dimensional (3D) perspective view representation of unit cells deployed as metasurface modules proximate to a server for noise cancellation, in accordance with various example embodiments and implementations of the subject disclosure.

FIG. 5 is a two-dimensional side view representation of example unit-cells including one enlarged unit cell showing various dimensions that determine the unit cell's resonance frequency, in accordance with various example embodiments and implementations of the subject disclosure.

FIG. 6 is a graphical representation of resulting absorption coefficient values of the three unit-cell of FIG. 3, indicating three very high reflection coefficient values for three different frequencies resulting in multiband frequency absorption, in accordance with various embodiments and implementations of the subject disclosure.

FIG. 7 is a graphical representation of resulting absorption coefficient values of three other unit-cells (relative to FIG. 4), showing three very high reflection coefficient values for three different frequencies, resulting in broadband frequency absorption, in accordance with various example embodiments and implementations of the subject disclosure

FIG. 8A is a side view representation of example noise canceling Helmholtz resonator metasurface modules coupled to respective blanking panels for deploying in respective rack slots above and below a server, in accordance with various example embodiments and implementations of the subject disclosure.

FIG. 8B is a front view representation of example noise canceling Helmholtz resonator metasurface modules coupled to respective blanking panels for deploying in respective rack slots above and below a server, in accordance with various example embodiments and implementations of the subject disclosure.

FIG. 9A is a 3D perspective view representation of example noise canceling Helmholtz resonator metasurface modules coupled to respective blanking panels for deploying in respective rack slots above and below a server, in accordance with various example embodiments and implementations of the subject disclosure.

FIG. 9B is a two-dimensional side view representation of unit cells deployed as metasurface modules proximate to a server housing top surface and bottom surface, in accordance with various example embodiments and implementations of the subject disclosure.

FIG. 10 is a 3D perspective view representation of unit cells deployed as metasurface modules proximate to a server housing top surface, bottom surface and side surfaces for noise cancellation, in accordance with various example embodiments and implementations of the subject disclosure.

### DETAILED DESCRIPTION

Various embodiments and implementations of the technology described herein are generally directed towards a sound absorbing device based on inverted phase cancellation, and more particularly towards one or more metasurface modules including Helmholtz resonators deployed proximate to a server. In one implementation, the metasurface modules are configured to be deployed on the sidewalls of a server rack in which the server is located. In another implementation, the metasurface modules are configured to be deployed in a server rack above and/or below a server; these can be deployed in unused server rack slots. A blanking panel can be coupled to the metasurface module to occupy the opening of an otherwise unused rack slot.

The technology described herein facilitates the design and implementation of such unit cells into metasurfaces that can be configured and positioned to efficiently absorb and dissipate sound waves of a specific frequency. Significantly, the use of metasurfaces as described herein do not increase the heat levels of computing devices substantially compared to existing technologies for sound absorption that do not facilitate ventilation/do not dissipate the heat very well. The specific frequency can be of any frequency/narrowband frequency range over a broad range of audible frequencies, or even subsonic (below 20 Hz)/supersonic frequencies (up to about 20,000 Hz).

Reference throughout this specification to “one embodiment,” “an embodiment,” “one implementation,” “an implementation,” etc. means that a particular feature, structure, or characteristic described in connection with the embodiment/implementation is included in at least one embodiment/implementation. Thus, the appearances of such a phrase “in one embodiment,” “in an implementation,” etc. in various places throughout this specification are not necessarily all referring to the same embodiment/implementation. Furthermore, the particular features, structures, or characteristics may be combined in any suitable manner in one or more embodiments/implementations. It also should be noted that terms used herein, such as “optimize,” “optimization,” “optimal,” “optimally” and the like only represent objectives to move towards a more optimal state, rather than necessarily obtaining ideal results. For example, “optimal” placement of a subnet means selecting a more optimal subnet over another option, rather than necessarily achieving an optimal result. Similarly, “maximize” means moving towards a maximal state (e.g., up to some processing capacity limit), not necessarily achieving such a state.

Further, it is to be understood that the present disclosure will be described in terms of a given illustrative architecture; however, other architectures, structures, substrate materials and process features, and steps can be varied within the scope of the present disclosure.

It will also be understood that when an element such as a layer, region or substrate is referred to as being “on” or “over” another element, it can be directly on the other element or intervening elements can also be present. In contrast, only if and when an element is referred to as being “directly on” or “directly over” another element, are there no intervening element(s) present. Note that orientation is generally relative; e.g., “on” or “over” can be flipped, and if so, can be considered unchanged, even if technically appearing to be under or below/beneath when represented in a flipped orientation. It will also be understood that when an element is referred to as being “connected” or “coupled” to another element, it can be directly connected or coupled to the other element or intervening elements can be present. In contrast, only if and when an element is referred to as being “directly connected” or “directly coupled” to another element, are there no intervening element(s) present.

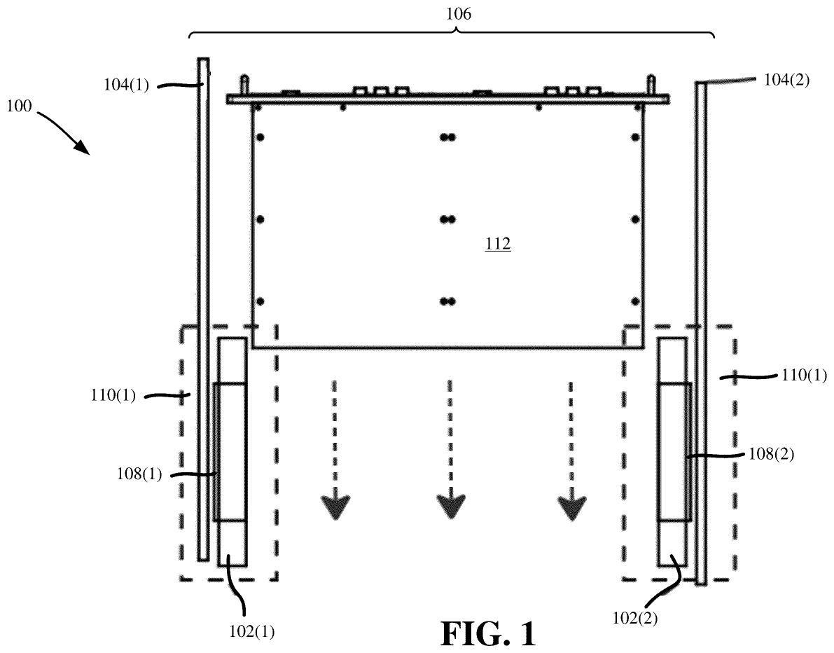

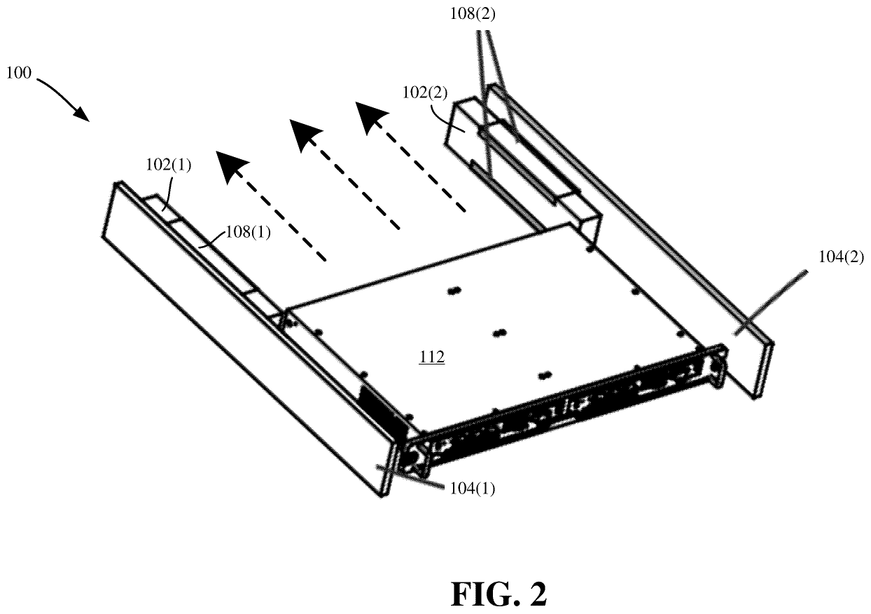

FIG. 1 (top view) and FIG. 2 (3D view) show a system 100 that includes metasurface modules 102(1) and 102(2) deployed on sidewalls 104(1) and 104(2), respectively, of a server rack 106. Couplings 108(1) and 108(2), such as magnetic couplings, can be used to attach the metasurface modules 102(1) and 102(2) to the sidewalls 104(1) and 104(2).

The general deployment positions of the metasurface modules 102(1) and 102(2), represented in FIG. 1 by the dashed boxes 110(1) and 110(2), respectively, are shown as generally parallel to and behind a server 112 (including its server housing). As a result, the airflow and corresponding noise emanating from the server 112 via its server fan(s), represented by the dashed arrows in FIGS. 1 and 2, is parallel to the metasurfaces and perpendicular to their unit cell resonator openings as described herein. Significantly, the airflow to the surrounding environment is substantially unobstructed by the metasurface modules 102(1) and 102(2).

In larger server racks such as 9U to 42U height (where “U” represents rack units), significant gaps often exist between individual servers (e.g., the server 112) and the rack enclosure 106, as shown in FIG. 1. The coupling (e.g., magnetic or mechanical attachment) of a metasurface within these gaps are able achieve efficient noise suppression over one or multiple peak noise frequencies. Indeed, such an acoustic metasurface can be designed as a wideband or multiband noise absorber, utilizing Helmholtz resonator principles perpendicular to the direction of airflow. This can enhance noise reduction across a broader frequency range while leveraging the existing rack structure for seamless integration, thereby maintaining airflow and thermal management efficiency. Notwithstanding, more customized modular metasurfaces can be designed and deployed, e.g., for one dominant peak frequency (or a small number of dominant peak frequencies) of a particular type of server.

To summarize thus far, the technology described herein is directed, in part, to a general-purpose noise absorbing module as a server rack customization feature for suppressing multiband/wideband reflected sound waves, e.g., with less than 10 dB suppression. The wideband/multiband metasurface noise absorbers described herein are specifically engineered for integration within the gaps of server rack enclosures. One alternative features a customizable magnetic attachment mechanism that allows the metasurface to be easily affixed to the walls of server racks. The magnetic attachment facilitates quick and non-invasive installation, leveraging the existing rack structure while maintaining optimal airflow and thermal performance. The side modules are not designed to achieve larger suppression such as above 10 dB, but are intended to suppress multiband and/or wideband peaks with <10 dB suppression capabilities; the sidewall mounted modules suppress reflected and standing audio waves.

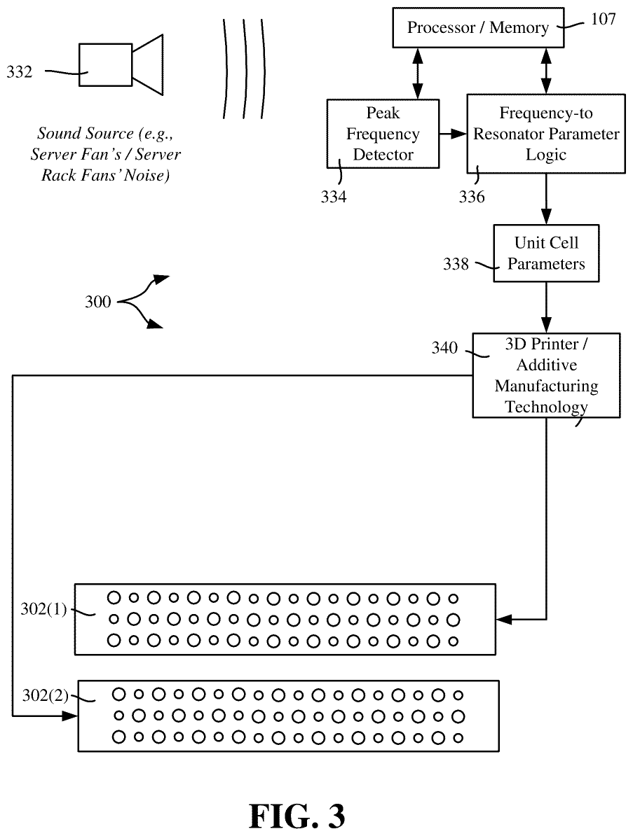

FIG. 3 shows a generalized block diagram of an example metasurface design system 300 including a sound source 332 such as server fan/fans of a rack of servers that generate undesirable noise including at one or more frequencies that are to be absorbed based on the technology described herein. The design can employ advanced broadband techniques, e.g., including a superposition design method, geometrical design method, and/or super-cell structures, to effectively suppress a broad spectrum of noise frequencies. Multiple frequency cancellation is based on using different Helmholtz resonator dimensions in the array that resonate at multiple frequencies to provide a multi/wide-band noise suppression, which provides a comprehensive noise reduction solution that enhances the acoustic environment of large server installations.

A frequency measurement tool can be used as a peak frequency detector 334 or the like to determine which approximate narrowband frequency, frequencies or wide band of frequencies to cancel as described herein. As will be seen, each such frequency is absorbed extremely efficiently by the technology described herein; for a single frequency (e.g., one of a multiband of frequencies), a narrow band of nearby frequencies also can be reduced to a lesser, but still desirable, extent.

Once the frequencies to cancel are determined, frequency-to resonator parameter logic 336 can be used to determine the parameters 338 of unit cells that can inverse phase cancel those frequencies. The parts of the unit cell can be constructed with 3D printer/additive manufacturing technology 340, that is, printing the metasurface supporting structure in conjunction with omitting printing of the unit cell resonators, which are thus air cavities.

The unit cells are based on the principles of Helmholtz resonators, which are acoustic cavities with a small neck port or opening that are highly effective at absorbing specific frequencies via resonance. For example, the resonant frequency (f_{resonance}) of a classical Helmholtz resonator with respect to frequencies in the audible range is determined by:

$${f}_{resonance} = \frac{c}{2 π} \sqrt{\frac{S}{{L}_{p} V}}$$

where c is the speed of sound, S is the neck port cross-sectional area, Lₚ=L_{neck}+1.7r_{neck} (for a cylindrical neck port) and V is the unit cell's cavity chamber's volume.

The unit cells, each represented as a small circle in FIG. 3, are incorporated into the metasurfaces 302(1) and 302(2), which can then be positioned to cancel the noise source at the determined frequencies or range of frequencies. In one implementation, each metasurfaces 302(1) and 302(2) contains an array of the unit cell resonator units arranged in a two-dimensional pattern. For absorbing a server's fan noise, for example, the metasurfaces 302(1) and 302(2) can be positioned proximate to the server's location as shown in FIGS. 1 and 2.

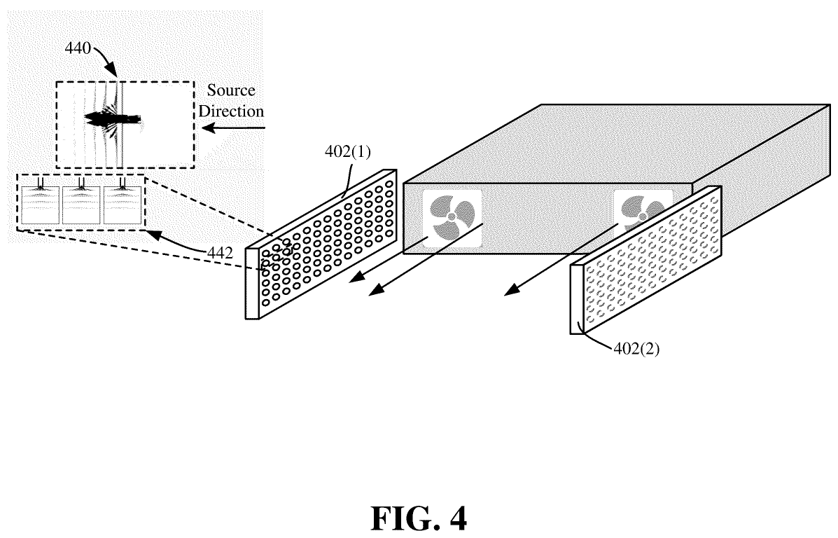

As generally represented in FIG. 4, when incident sound waves (block 440) interact with the metasurfaces, the variable Helmholtz resonators (three of which are enlarged in dashed block 442) within the array selectively absorb the corresponding frequencies via inverse phase cancellation. As sound waves enter the resonators (e.g., the resonator 118) through the neck port, they create pressure fluctuations within the cavities. By engineering the geometrical parameters of the cavity/air chamber, the resulting resonance frequency of each unit cell creates a It phase shift reflected wave with respect to the incident wave, in which the two sets of waves with opposite phase cancel, effectively absorbing the frequency. Note that these pressure fluctuations also cause the air inside the cavities to oscillate, effectively converting acoustic energy into kinetic energy. This kinetic energy is then dissipated as heat through viscous losses in the narrow neck of the resonators, however the heat dissipation is appreciably better relative to traditional sound absorbers and does not significantly affect thermal performance of a server.

The designed unit cell only needs air and its surrounding acoustic hard boundaries. This is different from other approaches using porous and fibrous materials and gradient index materials. The materials and the compact design in mm-scale/deeply sub-wavelength facilitate fabricating the unit cell as a thin, light-weight, and cost effective absorber with 3D printing technology.

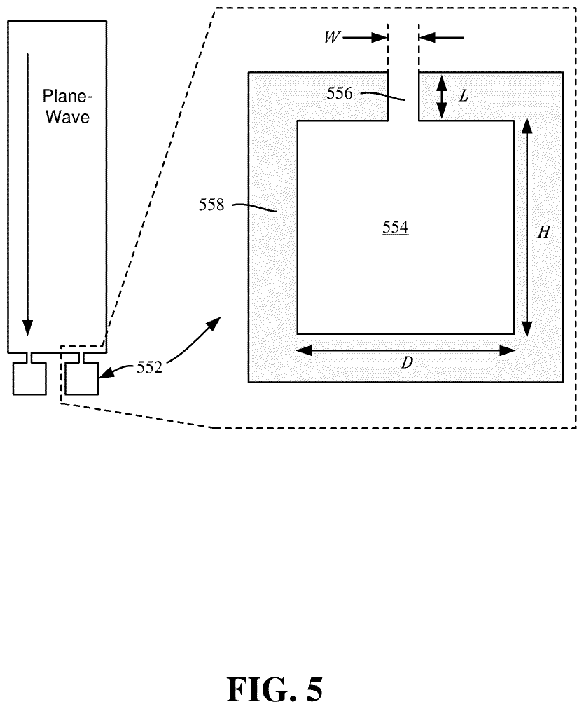

As generally represented in FIG. 5, each unit cell 552 comprises a cavity, or air chamber 554, often with a neck port 556 that exposes the air chamber to the air/incoming sound waves, with dimensions engineered to target a particular frequency or a narrowband range of frequencies of interest. The dimensions of the air chamber 554 and neck port 556 for a given unit cell are designed based on generally desired narrow band of acoustic frequencies to cancel.

Differently-dimensioned unit cells, e.g., interleaved in a pattern on a metasurface, allow the unit cells of the metasurface to resonate at their corresponding frequencies when exposed to sound waves of those frequencies. When constructed, e.g., as part of the 3D printing of the metasurface structure, the air chamber 554 and neck port 556, which are hollow to contain air, are enclosed in a supporting structure 558 through which the neck port 556 extends to couple the chamber 554 to the air propagating the sound wave.

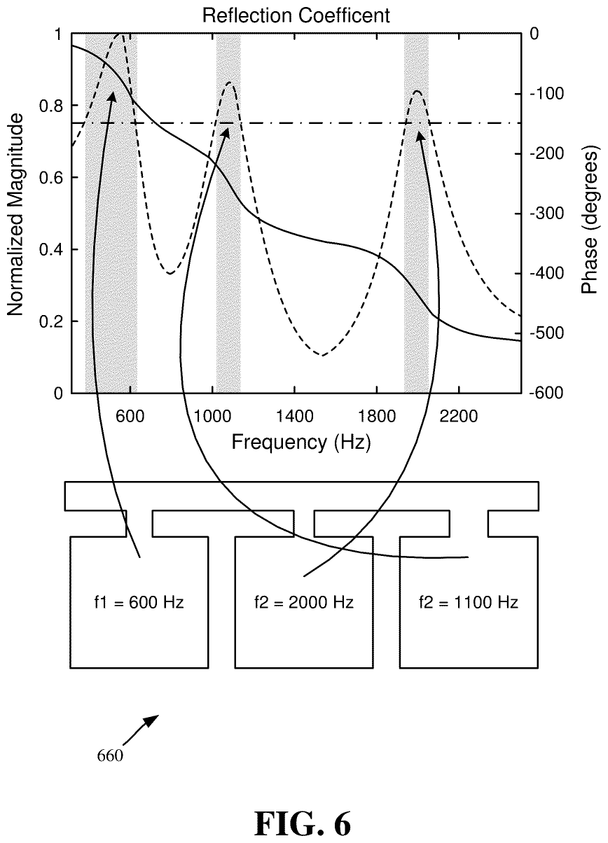

FIG. 6 shows the concept of a metasurface of a partial group of unit cells 660 designed for noise canceling three distinct frequencies, that is, the metasurface is designed for multiband noise cancelation. As described herein, an illustrative example of a tri-band sound absorption metamaterial results from the geometry of the structure, designed using the equations described herein for Helmholtz resonators that target three discrete frequencies. The effectiveness of the design can be verified by plotting the reflection coefficient of the proposed structure across the frequency spectrum, as shown in FIG. 6. The gray areas in the plot highlight regions of high absorption, exceeding seventy-five percent at the three intended frequencies.

A metasurface structure can be extended to encompass additional frequency bands. However, this extension comes at the expense of reduced absorption as the frequency bands widen. This phenomenon is also discernible in the plot of FIG. 6, where the lowest frequency exhibits nearly perfect absorption (greater than ninety-eight percent), while the highest frequency achieves a still highly beneficial absorption rate of around eighty percent.

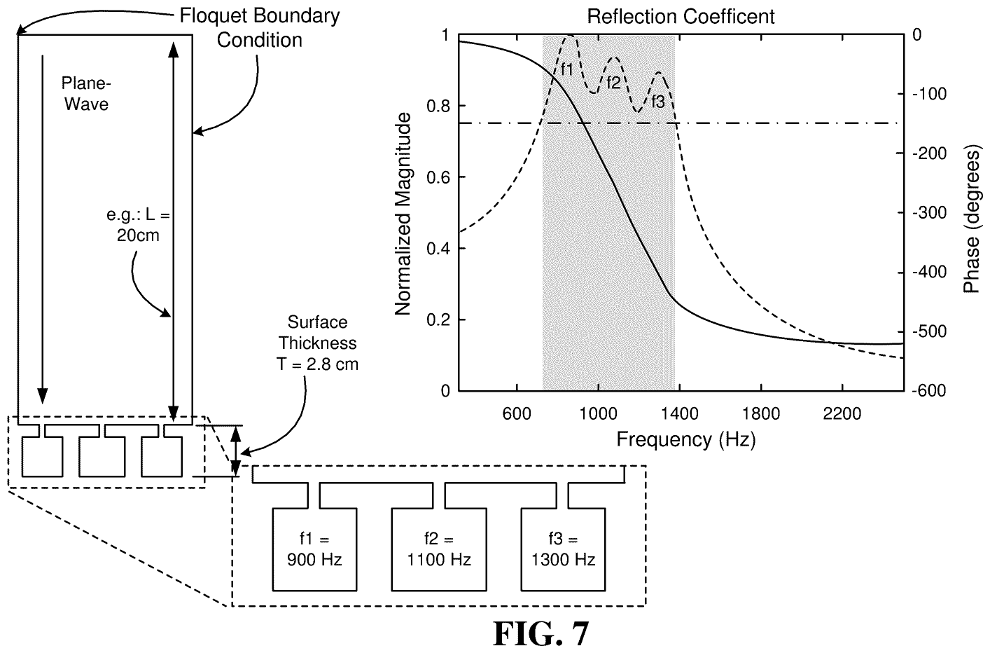

As noted herein, one prominent limitation of Helmholtz resonators, in contrast to other existing methods, is their narrow-band nature. This limitation is ameliorated by organizing sub-cells with resonant frequencies in close proximity to each other. Such an arrangement broadens the resonant frequency within the super-cell and the overall structure. As depicted in FIG. 7, this sub-cell approach yields high absorption rates (greater than seventy-five percent), spanning a broadband range from about 750 Hz to 1400 Hz, based on a pattern of three interleaving resonators designed for absorbing relatively close frequencies of 900 Hz, 1100 Hz and 1100 Hz. Note that a single metasurface can be designed for both broadband and multiband frequency absorption, and/or different multiple metasurfaces can be deployed.

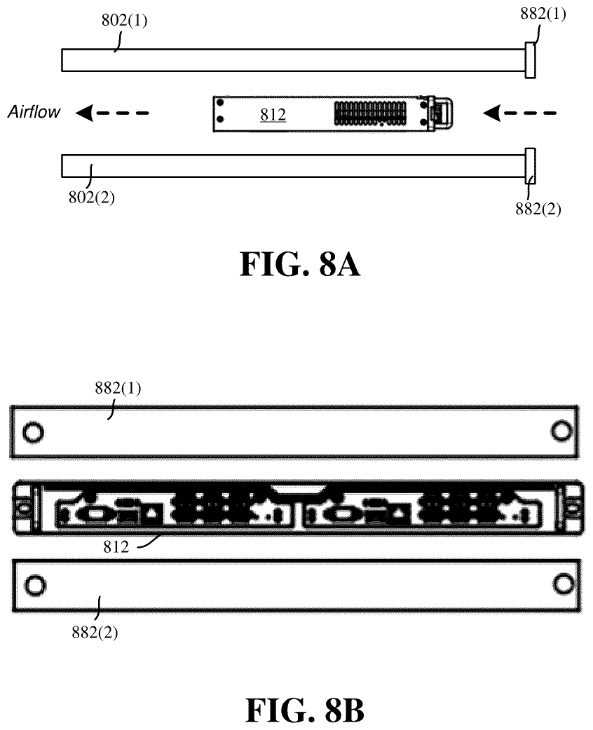

Turning to modular metasurface panels that can be deployed as a server rack accessory for greater than 10 dB suppression, noise-absorbing metasurfaces 802(1) and 802(2) can be attached/positioned above and below a server 812, e.g., in the gaps (unused rack slot locations) between stacked servers, as generally shown in FIGS. 8A and 8B. For cosmetic (and dust reduction) purposes, the metasurfaces 802(1) and 802(2) can be coupled to blanking panels 882(1) and 882(2), e.g., coupled to the front of a server rack (not shown). By targeting one frequency, multiple frequencies or a wide range of frequencies, such metasurface-equipped blanking panels significantly reduce noise levels, contributing to a quieter and more efficient server rack environment. This is a modular and scalable solution, where the metasurface equipped blanking panels can be easily installed and customized to fit various rack configurations (1U/2U, vented/non-vented), provide different levels of noise reduction, and so forth.

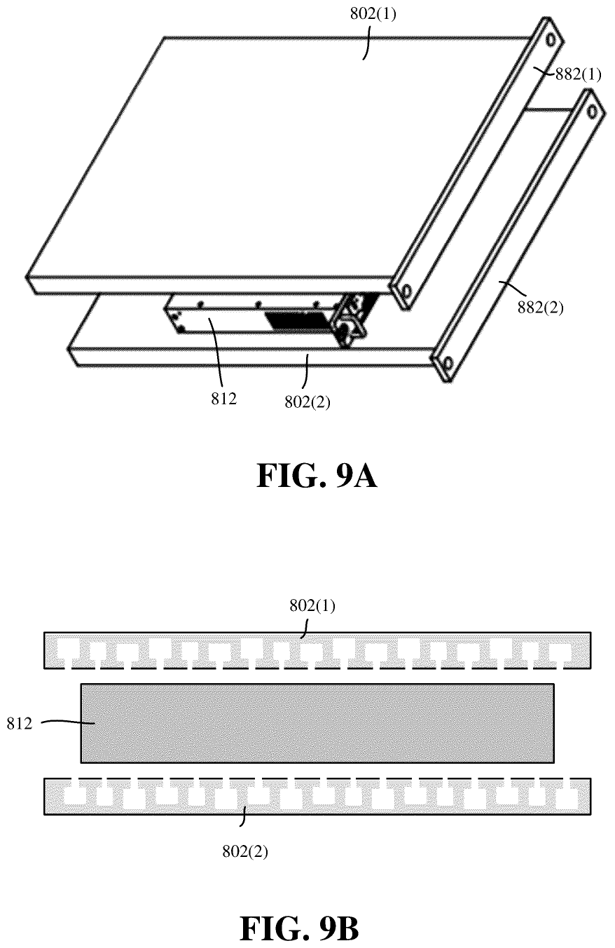

FIG. 9A shows a 3D perspective view of a broadband noise absorbing modules 802(1) and 802(2) of FIGS. 8A and 8B with blanking panels 882(1) and 882(2), e.g., as a built-in/snap-on feature to a server rack. FIG. 9B shows a side view in which the unit cells are visible, to emphasize that differently-dimensioned unit cells can be patterned in a metasurface. Note that the pattern need not be an even array, and there can be more unit cells of one size than another, e.g., if it is desirable to absorb one large frequency peak more than a smaller peak of another frequency.

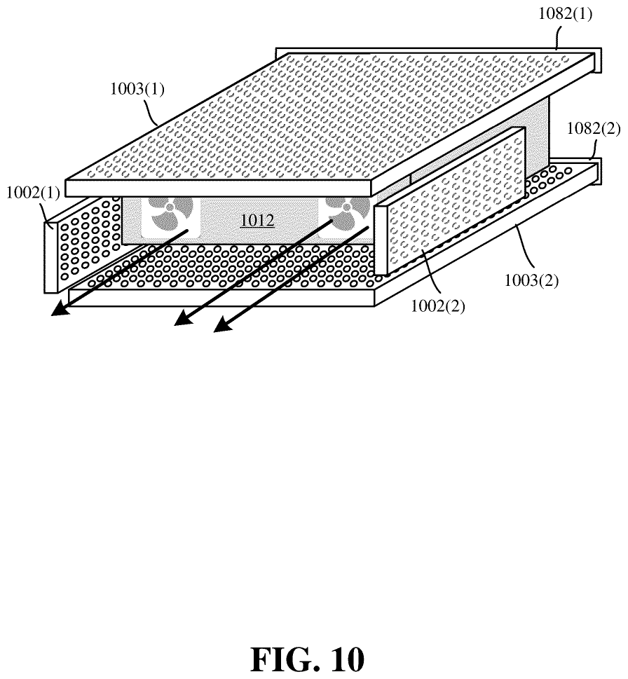

FIG. 10 shows the concept of combining both side-panel metasurfaces 1002(1) and 1002(2) and blanking panel-type metasurfaces 1003(1) and 1003(2). As in FIGS. 1 and 2, the side-panel metasurfaces 1002(1) and 1002(2) can be attached to the server rack's sidewalls, while the blanking panel-type metasurfaces 1003(1) and 1003(2) can be attached to slots above and below the server 1012. Although the unit cells are perpendicular to the direction of the airflow, significant noise absorption results, without significantly obstructing the airflow. Note that the different metasurfaces need not be the same, e.g., the side-panel metasurfaces 1002(1) and 1002(2) can be wideband noise suppressors, while the blanking panel-type metasurfaces 1003(1) and 1003(2) can be multiband noise suppressors, (or vice-versa).

One or more implementations and embodiments can be included in a system, such as described and represented in the drawing figures herein. The system can include an acoustic metasurface including Helmholtz resonators. The acoustic metasurface can be configured for deployment of the acoustic metasurface by coupling to a server rack. When the acoustic metasurface is coupled to the server rack proximate to a server, the acoustic metasurface can be located to facilitate unobstructed or substantially unobstructed airflow from the at least one fan to a surrounding environment, in conjunction with suppressing at least some noise generated by at least one fan of the server.

The Helmholtz resonators can be respective Helmholtz resonators that can include respective open cavities, and when deployed within the server rack proximate to the server, the respective open cavities can be substantially perpendicular to a direction of the airflow.

When the acoustic metasurface is coupled to the server rack proximate to the server, the acoustic metasurface can be on a side wall of the server rack adjacent to a side of the server. When the acoustic metasurface can be coupled to the server rack, the acoustic metasurface can be magnetically coupled to the side wall of the server.

The Helmholtz resonators of the acoustic metasurface can be configured to suppress multiple frequencies corresponding to the at least some noise generated by the at least one fan of the server.

When the acoustic metasurface is coupled to the server rack proximate to the server, the acoustic metasurface can be above a top surface of the server. The acoustic metasurface can be coupled to a blanking panel and can occupy a rack slot above the server. The Helmholtz resonators of the acoustic metasurface can be configured to suppress multiple frequencies corresponding to the at least some noise generated by the at least one fan of the server.

When the acoustic metasurface is coupled to the server rack proximate to the server, the acoustic metasurface can be below a bottom surface of the server.

The acoustic metasurface can be coupled to a blanking panel and can occupy a rack slot beneath the server.

The Helmholtz resonators of the acoustic metasurface can be configured to suppress multiple frequencies corresponding to the at least some noise generated by the at least one fan of the server.

The acoustic metasurface can be formed by a three-dimensional printer that prints the acoustic metasurface as a solid structure in layers, in conjunction with omitting printing of the Helmholtz resonators.

One or more implementations and embodiments can be included in a system, such as described and represented in the drawing figures herein. The system can include a first acoustic metasurface including first Helmholtz resonators. The first acoustic metasurface can be coupled to a server rack proximate to a first surface of a server housing. The system further can include a second acoustic metasurface including second Helmholtz resonators; the second acoustic metasurface can be coupled to the server rack proximate to a second surface of the server housing. The first acoustic metasurface can be located in the server rack to facilitate unobstructed or substantially unobstructed airflow from at least one fan within the server housing to a surrounding environment, in conjunction with suppressing a first amount of noise generated by the at least one fan. The second acoustic metasurface can be located in the server rack to facilitate unobstructed or substantially unobstructed airflow from the at least one fan within the server housing to the surrounding environment, in conjunction with suppressing a second amount of noise generated by the at least one fan.

The first acoustic metasurface can be coupled to the server rack on a first side wall of the server rack, the second acoustic metasurface can be coupled to the server rack on a second side wall of the server rack, and the first side wall can be opposite the second side wall.

The system further can include a third acoustic metasurface including third Helmholtz resonators, and a fourth acoustic metasurface including fourth Helmholtz resonators; the third acoustic metasurface can be located in the server rack above the server housing to facilitate unobstructed or substantially unobstructed airflow from the at least one fan within the server housing to a surrounding environment, in conjunction with suppressing a third amount of noise generated by the at least one fan, and the fourth acoustic metasurface can be located in the server rack below the server housing to facilitate unobstructed or substantially unobstructed airflow from the at least one fan within the server housing to a surrounding environment, in conjunction with suppressing a fourth amount of noise generated by the at least one fan.

The first acoustic metasurface can be located in the server rack above the server housing, and wherein the second acoustic metasurface can be located in the server rack below the server housing. The server housing can be installed in a first rack slot of the server rack, the first acoustic metasurface can be coupled to a first blanking panel and can occupy a second rack slot directly above the first rack slot, and the second acoustic metasurface can be coupled to a second blanking panel and can occupy a third rack slot directly beneath the first rack slot.

One or more implementations and embodiments can be included in a system, such as described and represented in the drawing figures herein. The system can include a first acoustic metasurface including first Helmholtz resonators; the first acoustic metasurface can be configured for coupling to a first side wall of a server rack. The system further can include a second acoustic metasurface including second Helmholtz resonators; the second acoustic metasurface can be configured for coupling to a second side wall of the server rack. The system further can include a third acoustic metasurface including third Helmholtz resonators; the third acoustic metasurface can be configured for coupling to a rack slot of the server rack. The first acoustic metasurface, the second acoustic metasurface and the third acoustic metasurface can be located within the server rack proximate to a server installed in the server rack. The first acoustic metasurface, the second acoustic metasurface and the third acoustic metasurface can be oriented within the server rack substantially parallel to first, second and third surfaces, respectively, of the server, to facilitate unobstructed or substantially unobstructed airflow from at least fan of the server to a surrounding environment, in conjunction with suppressing noise generated by the at least one fan.

The third acoustic metasurface can be coupled to a blanking panel for covering at least part of an opening in the server rack corresponding to the rack slot.

The rack slot of the server rack can be a first rack slot above the server, and the system further can include a fourth acoustic metasurface including fourth Helmholtz resonators; the fourth acoustic metasurface can be configured for coupling to a second rack slot of the server rack below the server.

As can be seen, the technology described herein facilitates construction and deployment of modular metasurfaces of unit cells that can be deployed in a server rack. The metasurfaces are implemented in a practical, compact and lightweight surface configuration. As one example, the metasurface is highly useful in the context of mitigating server noise, including multiband and/or wideband frequencies. One unit-cell design achieved high sound absorption of an incoming sound wave at the frequency for which it was designed. Based on the technology described herein, thin, light-weight, and cost effective sound absorbers can be constructed, including by using 3D printing technology.

The above description of illustrated embodiments of the subject disclosure, comprising what is described in the Abstract, is not intended to be exhaustive or to limit the disclosed embodiments to the precise forms disclosed. While specific embodiments and examples are described herein for illustrative purposes, various modifications are possible that are considered within the scope of such embodiments and examples, as those skilled in the relevant art can recognize.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

As used in this application, the terms “component,” “system,” “platform,” “layer,” “selector,” “interface,” and the like are intended to refer to a computer-related resource or an entity related to an operational apparatus with one or more specific functionalities, wherein the entity can be either hardware, a combination of hardware and software, software, or software in execution. As an example, a component can be an apparatus with specific functionality provided by mechanical parts operated by electric or electronic circuitry. As yet another example, a component can be an apparatus that provides specific functionality through electronic components without mechanical parts, the electronic components can comprise a processor therein to execute software or firmware that confers at least in part the functionality of the electronic components.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances.

While the embodiments are susceptible to various modifications and alternative constructions, certain illustrated implementations thereof are shown in the drawings and have been described above in detail. It should be understood, however, that there is no intention to limit the various embodiments to the specific forms disclosed, but on the contrary, the intention is to cover all modifications, alternative constructions, and equivalents falling within the spirit and scope.

In addition to the various implementations described herein, it is to be understood that other similar implementations can be used or modifications and additions can be made to the described implementation(s) for performing the same or equivalent function of the corresponding implementation(s) without deviating therefrom. Still further, multiple processing chips or multiple devices can share the performance of one or more functions described herein, and similarly, storage can be effected across a plurality of devices. Accordingly, the various embodiments are not to be limited to any single implementation, but rather are to be construed in breadth, spirit and scope in accordance with the appended claims.

What is claimed is:

1. A system, comprising:
an acoustic metasurface comprising Helmholtz resonators,
wherein the acoustic metasurface is configured for deployment of the acoustic metasurface by coupling to a server rack, and
wherein, when the acoustic metasurface is coupled to the server rack proximate to a server, the acoustic metasurface is located to facilitate unobstructed or substantially unobstructed airflow from the at least one fan to a surrounding environment, in conjunction with suppressing at least some noise generated by at least one fan of the server.

2. The system of claim 1, wherein the Helmholtz resonators are respective Helmholtz resonators that comprise respective open cavities, and wherein, when deployed within the server rack proximate to the server, the respective open cavities are substantially perpendicular to a direction of the airflow.

3. The system of claim 1, wherein, when the acoustic metasurface is coupled to the server rack proximate to the server, the acoustic metasurface is on a side wall of the server rack adjacent to a side of the server.

4. The system of claim 3, wherein, when the acoustic metasurface is coupled to the server rack, the acoustic metasurface is magnetically coupled to the side wall of the server.

5. The system of claim 1, wherein the Helmholtz resonators of the acoustic metasurface are configured to suppress multiple frequencies corresponding to the at least some noise generated by the at least one fan of the server.

6. The system of claim 1, wherein, when the acoustic metasurface is coupled to the server rack proximate to the server, the acoustic metasurface is above a top surface of the server.

7. The system of claim 6, wherein the acoustic metasurface is coupled to a blanking panel and occupies a rack slot above the server.

8. The system of claim 6, wherein the Helmholtz resonators of the acoustic metasurface are configured to suppress multiple frequencies corresponding to the at least some noise generated by the at least one fan of the server.

9. The system of claim 1, wherein, when the acoustic metasurface is coupled to the server rack proximate to the server, the acoustic metasurface is below a bottom surface of the server.

10. The system of claim 9, wherein the acoustic metasurface is coupled to a blanking panel and occupies a rack slot beneath the server.

11. The system of claim 9, wherein the Helmholtz resonators of the acoustic metasurface are configured to suppress multiple frequencies corresponding to the at least some noise generated by the at least one fan of the server.

12. The system of claim 1, wherein the acoustic metasurface is formed by a three-dimensional printer that prints the acoustic metasurface as a solid structure in layers, in conjunction with omitting printing of the Helmholtz resonators.

13. A system, comprising:
a first acoustic metasurface comprising first Helmholtz resonators, wherein the first acoustic metasurface is coupled to a server rack proximate to a first surface of a server housing; and
a second acoustic metasurface comprising second Helmholtz resonators, wherein the second acoustic metasurface is coupled to the server rack proximate to a second surface of the server housing,
wherein the first acoustic metasurface is located in the server rack to facilitate unobstructed or substantially unobstructed airflow from at least one fan within the server housing to a surrounding environment, in conjunction with suppressing a first amount of noise generated by the at least one fan, and
wherein the second acoustic metasurface is located in the server rack to facilitate unobstructed or substantially unobstructed airflow from the at least one fan within the server housing to the surrounding environment, in conjunction with suppressing a second amount of noise generated by the at least one fan.

14. The system of claim 13, wherein the first acoustic metasurface is coupled to the server rack on a first side wall of the server rack, wherein the second acoustic metasurface is coupled to the server rack on a second side wall of the server rack, and wherein the first side wall is opposite the second side wall.

15. The system of claim 14, further comprising a third acoustic metasurface comprising third Helmholtz resonators, and a fourth acoustic metasurface comprising fourth Helmholtz resonators, wherein the third acoustic metasurface is located in the server rack above the server housing to facilitate unobstructed or substantially unobstructed airflow from the at least one fan within the server housing to a surrounding environment, in conjunction with suppressing a third amount of noise generated by the at least one fan, and wherein the fourth acoustic metasurface is located in the server rack below the server housing to facilitate unobstructed or substantially unobstructed airflow from the at least one fan within the server housing to a surrounding environment, in conjunction with suppressing a fourth amount of noise generated by the at least one fan.

16. The system of claim 13, wherein the first acoustic metasurface is located in the server rack above the server housing, and wherein the second acoustic metasurface is located in the server rack below the server housing.

17. The system of claim 16, wherein the server housing is installed in a first rack slot of the server rack, wherein the first acoustic metasurface is coupled to a first blanking panel and occupies a second rack slot directly above the first rack slot, and wherein the second acoustic metasurface is coupled to a second blanking panel and occupies a third rack slot directly beneath the first rack slot.

18. A system, comprising:
a first acoustic metasurface comprising first Helmholtz resonators, wherein the first acoustic metasurface is configured for coupling to a first side wall of a server rack;
a second acoustic metasurface comprising second Helmholtz resonators, wherein the second acoustic metasurface is configured for coupling to a second side wall of the server rack; and
a third acoustic metasurface comprising third Helmholtz resonators, wherein the third acoustic metasurface is configured for coupling to a rack slot of the server rack,
wherein the first acoustic metasurface, the second acoustic metasurface and the third acoustic metasurface are located within the server rack proximate to a server installed in the server rack, and
wherein the first acoustic metasurface, the second acoustic metasurface and the third acoustic metasurface are oriented within the server rack substantially parallel to first, second and third surfaces, respectively, of the server, to facilitate unobstructed or substantially unobstructed airflow from at least fan of the server to a surrounding environment, in conjunction with suppressing noise generated by the at least one fan.

19. The system of claim 18, wherein the third acoustic metasurface is coupled to a blanking panel for covering at least part of an opening in the server rack corresponding to the rack slot.

20. The system of claim 18, wherein the rack slot of the server rack is a first rack slot above the server, and further comprising a fourth acoustic metasurface comprising fourth Helmholtz resonators, wherein the fourth acoustic metasurface is configured for coupling to a second rack slot of the server rack below the server.
